(19) United States
(12) Patent Application Publication
(10) Pub. No.: US 2012/0162044 A1
(43) Pub. Date: Jun. 28, 2012

(54) Systems and Methods for Mounting an Object to an Edge of a Structure

(75) Inventors: David M. Lettkeman, Paker, CO (US); Patrick Harold Reynolds, Lakewood, CO (US)

(73) Assignee: DISH Network L.L.C., Englewood, CO (US)

(21) Appl. No.: 12/979,597

(22) Filed: Dec. 28, 2010

(51) Int. Cl. H01Q 1/12; H05K 13/00; F16M 13/00

(52) U.S. Cl. 343/880; 248/274.1; 29/592.1

(57) ABSTRACT

Apparatus and methods are described for mounting an object to an edge of a structure. A plate is utilized to provide additional rigidity for mounting an object to a structure. The plate includes a first surface configured to slide between the structure and an object mounted to the structure with at least one securing mechanism. The plate includes a first slot positioned along a first peripheral edge of the plate. The first slot is configured to align with and prevent interference of the plate with the securing mechanism during the slide and to receive the securing mechanism. The plate includes a second slot positioned along the first peripheral edge. The second slot is configured to align with and prevent interference of the plate with the securing mechanism during the slide and to receive the securing mechanism.

### BACKGROUND

Objects, such as satellite antennas, are often mounted to the outside of a structure. Typically, a base of the satellite antenna is attached to the structure through appropriate fasteners, such as screws. A problem arises when the satellite antenna is mounted near the edge of the structure. An installer may be required to mount the satellite antenna in a position that does not allow the entire base of the satellite antenna to be mounted onto the structure. Thus, a portion of the base may extend outwards away from the structure. In some instances, this mounting configuration may not provide appropriate rigidity for securing the satellite antenna to the structure. Thus, more secure mounting arrangements are desired in order to adequately secure a satellite antenna or other device to the side of a structure, and more particularly, techniques are desired to retrofit existing satellite antenna installations.

### BRIEF DESCRIPTION OF THE DRAWINGS

The same number represents the same element or same type of element in all drawings.

FIG. 1A illustrates an embodiment of a satellite antenna mounting environment.

FIG. 1B illustrates another embodiment of a satellite antenna mounting environment in which the base is mounted in a different orientation with respect to the structure.

FIG. 2A illustrates an embodiment of a top plan view of a plate.

FIG. 2B illustrates an embodiment of a side view of the plate of FIG. 2A.

FIG. 3A illustrates an embodiment of a satellite antenna environment in which the base of the satellite antenna is in a first position.

FIG. 3B illustrates an embodiment of a satellite antenna environment in which the base of the satellite antenna is in a second position once the plate of FIG. 2 has been installed.

FIG. 4 illustrates an embodiment of a satellite mounting environment including the plate.

FIGS. 5A-5C illustrate embodiments of the positions of the plate with respect to the base during installation of the plate into an existing satellite antenna installation.

FIG. 6 illustrates an embodiment of a process for mounting a satellite antenna to a structure.

### DETAILED DESCRIPTION OF THE DRAWINGS

Described herein are apparatus, systems and methods for mounting objects to a structure. More particularly, described herein are techniques for increasing the rigidity of an object mounted to a structure. As described herein, a plate may be utilized to mount an object, such as a satellite antenna, to a structure. In at least one embodiment, the plate is utilized between a base of an object to be mounted (such as a satellite antenna) and the surface of the structure. The plate increases the rigidity of the object attached to the structure, thus more adequately securing the mounted object to the surface of the structure. In various embodiments, the plate is configured such that it may be utilized in both new installations as well as to retrofit previous mounting installations in order to provide additional rigidity to the mounted object.

At least one embodiment described herein is a plate for installing an object to a structure. The plate includes a first surface configured to slide between the structure and an object mounted to the structure. The object is mounted to the structure via at least one securing mechanism. The plate includes a first slot positioned along a first peripheral edge of the plate. The first slot is configured to align with and prevent interference of the plate with the securing mechanism during the slide and to receive the securing mechanism. A second slot is positioned along the first edge of the plate. The second slot is configured to align with and prevent interference of the plate with the securing mechanism during the slide and to receive the securing mechanism.

Another embodiment provides a method for mounting a satellite antenna to a structure. The method includes providing a base configured for attachment to the antenna and to the structure with a portion projecting from the structure and providing at least one securing mechanism configured to secure the base to the structure with a space therebetween in a first position and to rigidly secure the base to the structure in a second position. When the base is in the first position, the method comprises sliding a plate having at least one slot along a peripheral edge thereof in the space between the base and the structure with the slot aligned with and preventing interference of the plate with the securing mechanism. Following the sliding operation, the method includes operating the securing mechanism to secure the base to the structure in the second position with the plate supporting the portion projecting from the structure and the slot receiving the securing mechanism.

Another embodiment comprises a system for mounting a satellite antenna to a structure. The system includes a base attached to the antenna and to the structure having a portion projecting from the structure and at least one securing mechanism configured to secure the base to the structure in a first position and in a second position. The system further includes a plate mounted between the base and the structure configured to slide between the base and the structure with the base in the first position and to support the portion projecting from the structure with the base in the second position.

The techniques provided herein are described in the context of mounting a satellite antenna to a structure. More particularly, the techniques described herein are described with reference to the retrofitting of a satellite antenna installation along the edge of the structure. However, it is to be appreciated that the techniques described herein may be applied to installing any type of object to a structure in any type of orientation in which additional rigidity is desired.

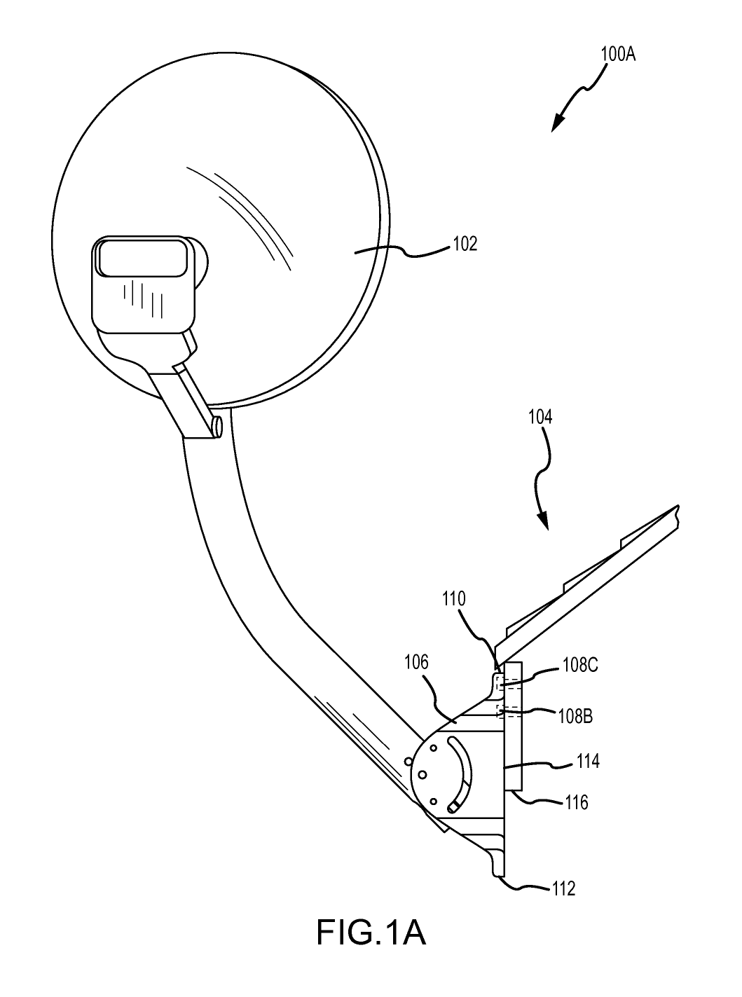

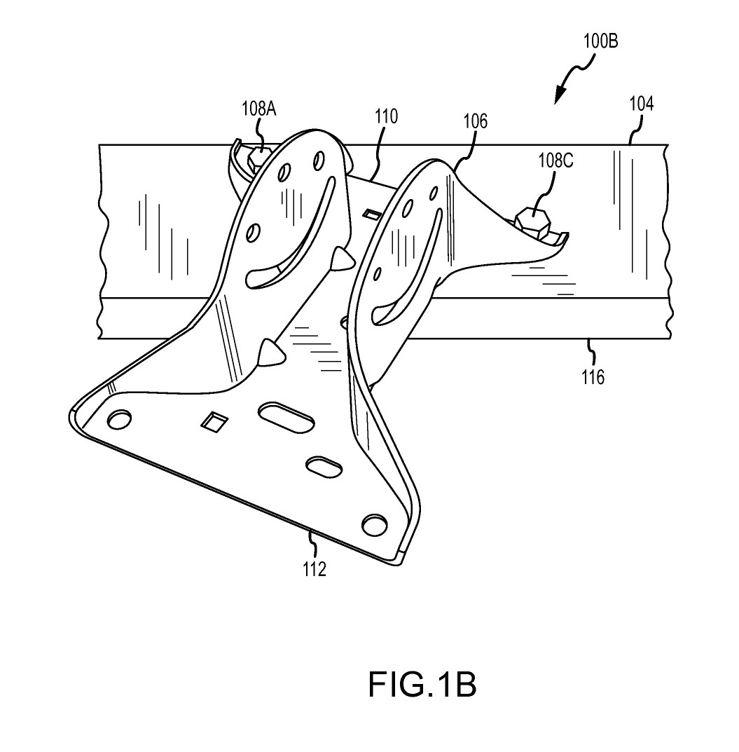

FIG. 1A illustrates an embodiment of a satellite antenna mounting environment 100A. More particularly, the environment 100A of FIG. 1A includes a satellite antenna 102 mounted to the fascia 114 of a structure 104. FIG. 1B illustrates another embodiment of a satellite antenna mounting environment 100B in which the base 106 is mounted in a different orientation with respect to the structure 104. The satellite antenna 102 is omitted from FIG. 1B to prevent obscuring the mounting components. Both FIGS. 1A and 1B include similar components securing the satellite antenna 102 and/or base to the structure 104 and will be described together below.

The satellite antenna 102 includes a base 106 attached to the structure 104 using at least one securing mechanism, such as the threaded members 108A, 108B and 108C. The threaded members 108A, 108B and 108C attach a first end 110 of the base 106 to the structure 104. More particularly, the base 106 may include a plurality of through holes (not shown in FIGS. 1A and 1B) configured to receive a threaded member 108A, 108B and 108C which secures the base 106 to the structure 104. In environment 100A (see FIG. 1A), the second end 112 of the base 106 projects outwards away from the edge 116 of the fascia of the structure 104. Likewise, in environment 100B (see FIG. 1B), a second end 112 of the base 106 projects outward away from an edge 116 of the structure 104. As described above, the base 106 alone may not provide sufficient rigidity to adequately secure the satellite antenna 102 to the structure 104 as configured in the satellite antenna mounting environments 100A and 100B. Techniques described below provide additional rigidity to the mounting of the base 106 within the environments 100A and 100B described above.

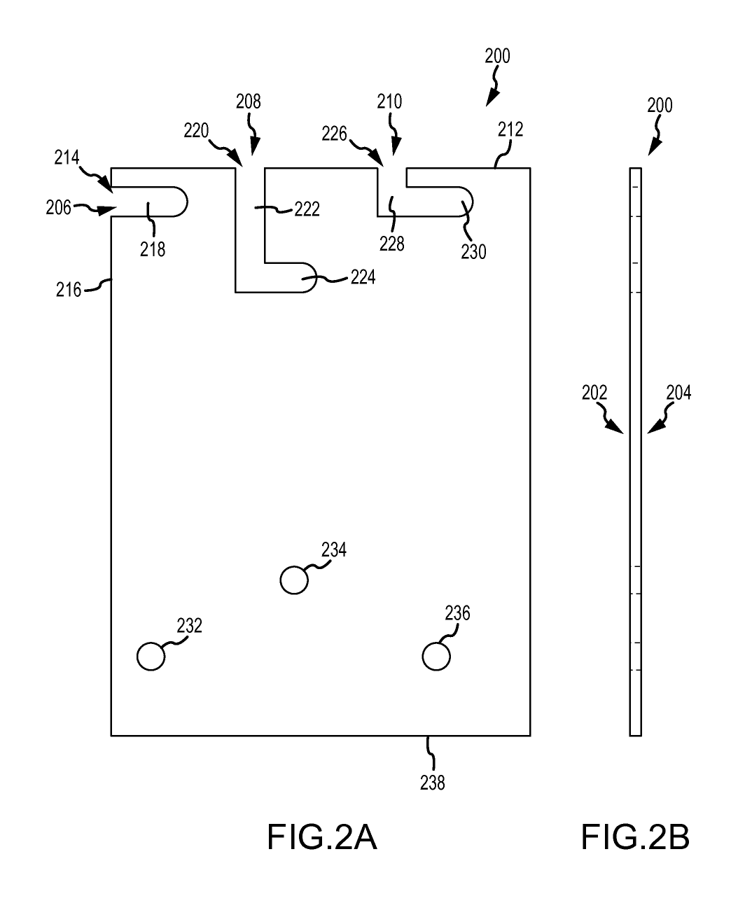

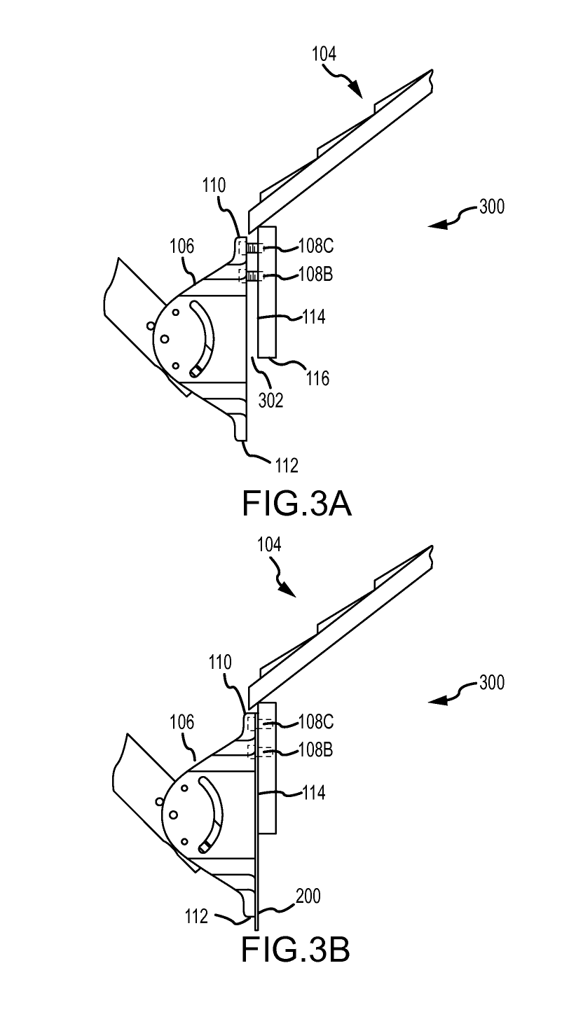

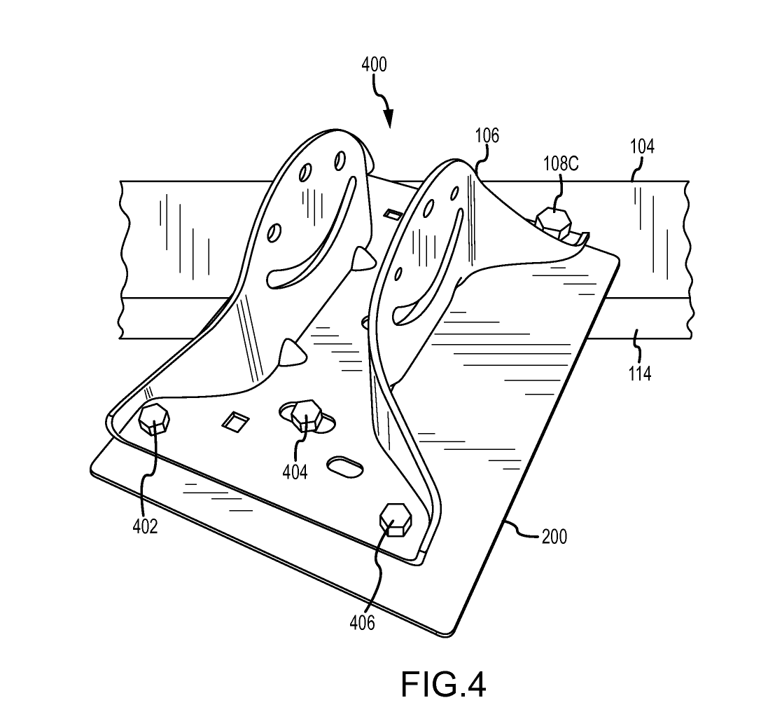

FIGS. 2A and 2B illustrate an embodiment of a plate 200 which may be utilized to provide additional rigidity within the satellite antenna mounting environment 100A. FIG. 2A illustrates an embodiment of a top plan view of the plate 200. FIG. 2B illustrates an embodiment of side view of the plate 200. FIG. 3A illustrates an embodiment of a satellite antenna environment 300 in which the base 106 of the satellite antenna 102 is in a first position. More particularly, the first position of the base 106 allows for installation of the plate into the mounting environment 300. FIG. 3B illustrates an embodiment of a satellite antenna environment 300 in which the base 106 of the satellite antenna 102 is in a second position once the plate 200 has been installed. FIG. 4 illustrates an embodiment of a satellite mounting environment 400 including the plate 200, similar to the satellite mounting environment 100B described above. The plate 200 will be described in reference to each of FIGS. 2A, 2B, 3A, 3B, 4 and 5.

The plate 200 provides additional rigidity for attaching the satellite antenna 102 to the structure 104. The plate 200 is configured to slide between the base 106 and the structure 104 and may be comprised of any appropriate type of material, such as a rigid metal. In a first position (see FIG. 3A), the threaded members 108A, 108B and 108C are loosened, creating a space 302 (see FIG. 3A) between the base 106 and the structure 104. This space 302 allows the plate 200 to slide between the base 106 and the structure 104. In a second position (see FIG. 3B), the threaded members 108A, 108B and 108C are tightened, compressing together the plate 200, the base 106 and the structure 104. In the second position, the base 106 is rigidly secured to the structure 104 with the plate 200 therebetween (see FIG. 3). Thus, the base 106 and satellite antenna 102 are less likely to un-attach from the structure 104 due to external forces, such as weather and the like.

Referring to FIG. 2B, the plate 200 includes a first surface 202 that slideably engages the surface of the structure 104. The plate 200 further includes a second surface 204 that slideably engages the bottom surface of the base 106. The plate 200 includes a plurality of slots 206, 208 and 210 (see FIG. 2A) positioned within the first and second surfaces 202 and 204. More particularly, the plurality of slots 206, 208 and 210 are positioned proximate the first peripheral edge 212 of the plate 200. The slots 206, 208 and 210 are configured to align with and prevent interference of the plate 200 with the threaded members 108A, 108B and 108C during the slide and to receive the threaded members 108A, 108B and 108C in the second position.

The first slot 206 includes an opening 214 positioned along the second peripheral edge 216 of the plate 200. In at least one embodiment, the first slot 206 includes an elongated channel 218 that receives the threaded member 108A. More particularly, the threaded member 108A slides along the elongated channel 218. In at least one embodiment, the elongated channel 218 forms a notch in the second peripheral edge 216 of the plate 200. However, it is to be appreciated that the elongated channel 218 may be formed in any shape depending on slide orientation and/or type of securing mechanism used to secure the base 106 to the structure 104. For example, the threaded members 108A, 108B and 108C may alternatively comprise other types of fasteners appropriate for securing the base 106 to the structure 104.

A second slot 208 includes an opening 220 along the first peripheral edge 212 of the plate 200. The second slot 208 may include an elongated channel 222 running generally parallel with the second peripheral edge 216. The second slot 208 further includes a notch 224 disposed adjacent a portion of the elongated channel 222. In other words, the notch 224 is disposed on a second end of the elongated channel 222 opposing the opening 220. As illustrated in FIG. 2A, in at least one embodiment, the second slot 208 is generally L-shaped and configured to receive and slideably engage a second securing mechanism 108B. The threaded member 108B slides along the elongated channel 222 into the notch 224. However, the second slot 208 may take any appropriate shape depending on desired design criteria. For example, the notch 224 may be positioned along any portion of the elongated channel 222 in order to correspond with through openings of the base 106 and the position of the threaded member 108B.

The third slot 210 includes an opening 226 along the first peripheral edge 212 of the plate 200. The third slot 210 may include an elongated channel 228 running generally parallel with the second peripheral edge 216. The third slot 210 further includes a notch 230 disposed adjacent a portion of the elongated channel 228. In other words, the notch 230 is disposed on a second end of the elongated channel 228 opposing the opening 226. As illustrated in FIG. 2A, in at least one embodiment, the third slot 210 is generally L-shaped and configured to slideably engage a third threaded member 108C. The threaded member 108C slides along the elongated channel 228 into the notch 230. However, the third slot 210 may take any appropriate shape depending on desired design criteria. For example, the notch 230 may be positioned along any portion of the elongated channel 228 in order to correspond with through openings of the base 106 and the position of the threaded member 108B. In at least one embodiment, the elongated channel 218 of the first slot 206 and the notch 230 of the third slot 210 are positioned parallel with one another on the plate 200.

As illustrated in FIG. 2A, a length of an elongated channel 218 of the second slot 208 is greater than a length of an elongated channel 228 of the third slot 210. The length of each of the elongated channel 220 and the elongated channel 228 may be determined based on a desired positioning of the threaded members 108B and 108C when the base 106 is in the second position (see FIG. 3B). This allows the plate 200 to slide around threaded members 108B and 108C which are not positioned parallel with one another.

In at least one embodiment, the plate 200 includes a plurality of though holes 232, 234 and 236 positioned proximate a third peripheral edge 238 of the plate 200. More particularly, the through holes 232, 234 and 236 are positioned on the edge 238 opposing the three slots 206, 208 and 210. The through holes 232, 234 and 236 are positioned to correspond with like through holes of the base 106. Each through hole 232, 234 and 236 is configured to receive a fastener 402, 404 and 406 (see FIG. 4) that secures the base 106 to the structure 104. While the plate 200 is illustrated as including three through holes 232, 234 and 236 that correspond with like through holes of the base 106, it is to be appreciated that any number of through holes 232, 234 and 236 may be included in the plate 200 depending on desired design criteria.

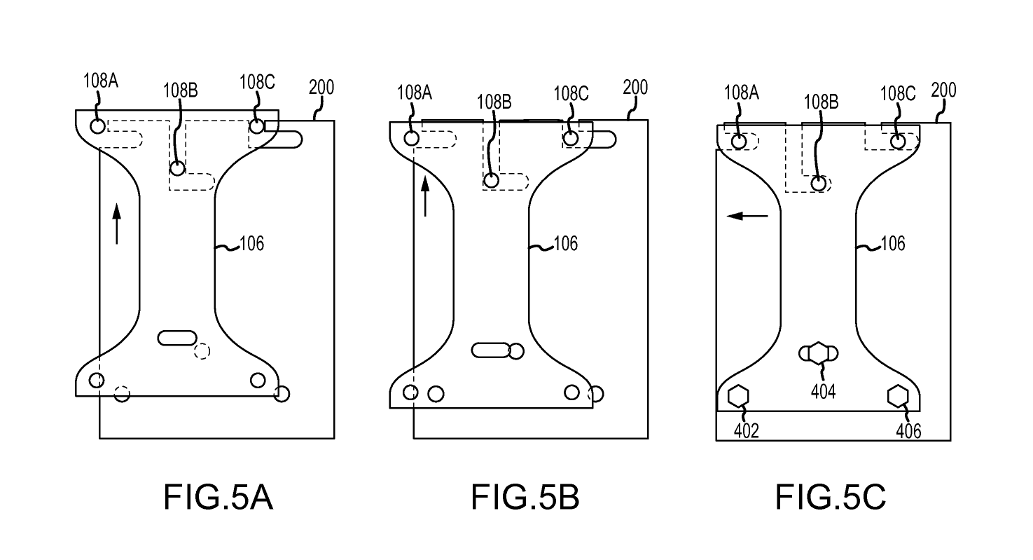

FIGS. 5A-5C illustrate the positions of the plate 200 with respect to the base 106 during installation of the plate 200 into an existing satellite antenna installation environment. First, the threaded members 108A, 108B and 108C are loosened to allow the plate 200 to slide between the base 106 and the structure 104. As illustrated in FIG. 5A, the second and third slots 208 and 210 are aligned with the threaded members 108B and 108C. In FIG. 5B, the plate 200 is slid towards the first end 110 of the base 106. Thus, the threaded members 108B and 108C are aligned with the ends of the elongated channels 222 and 228. In FIG. 5C, the plate 200 is slid towards the left of the base 106. Thus, the threaded member 108A is aligned with a right edge of the first slot 206. Similarly, the threaded member 108B and the threaded member 108C are aligned with right edges of the notches 224 and 230, respectively. Once the plate 200 is slid into place, the threaded members 108A-108C may be tightened to rigidly secure the base 106, the structure 104 and the plate 200. In at least one embodiment, a plurality of fasteners 402, 404 and 406 may be utilized to further secure the plate 200 to the base 106 via the through openings 232, 234 and 236.

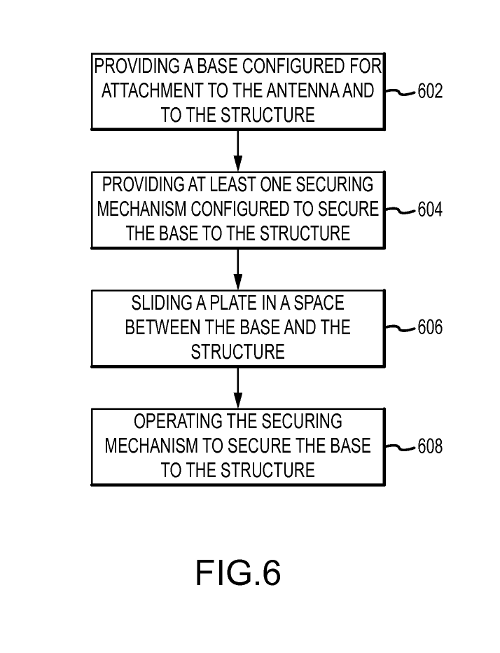

FIG. 6 illustrates an embodiment of a process for mounting a satellite antenna to a structure. The process will be described with reference to the satellite installation environments described above. The process of FIG. 6 may include other operations not illustrated for the sake of brevity.

The process includes providing a base 106 configured for attachment to the antenna 102 and to the structure 104 with a portion projecting from the structure 104 (operation 602). The process further includes providing at least one securing mechanism 108A, 108B and 108C configured to secure the base 106 to the structure 104 with a space 302 (see FIG. 3) therebetween in a first position and to rigidly secure the base 106 to the structure 104 in a second position (operation 604). With the base 106 in the first position, the process includes sliding a plate 200 having at least one slot 206, 208 and 210 along a peripheral edge 212 thereof in the space 302 between the base 106 and the structure 104 with the slot 206, 208 and 210 aligned with and preventing interference of the plate 200 with the securing mechanism 108A, 108B and 108C (operation 606). Following the sliding operation, the process includes operating the securing mechanism 108A, 108B and 108C to secure the base 106 to the structure 104 in the second position with the plate 200 supporting the portion projecting from the structure 104 and the slot 206, 208 and 210 receiving the securing mechanism 108A, 108B and 108C (operation 608).

Although specific embodiments were described herein, the scope of the invention is not limited to those specific embodiments. The scope of the invention is defined by the following claims and any equivalents therein.

We claim:

1. A system for mounting a satellite antenna to a structure comprising:
a base attached to the antenna and to the structure having a portion projecting from the structure;
at least one securing mechanism configured to secure the base to the structure in a first position and in a second position; and
a plate mounted between the base and the structure configured to slide between the base and the structure with the base in the first position and to support the portion projecting from the structure with the base in the second position,
the plate comprising at least one slot along a peripheral edge thereof configured to align with and prevent interference of the plate with the securing mechanism during the slide and to receive the securing mechanism in the second position.

2. The system of claim 1, wherein in the first position a space can be formed between the base and the structure for receiving the plate and in the second position the base is rigidly secured to the structure with the plate therebetween.

3. The system of claim 1, wherein the base includes a through hole and the securing mechanism comprises a fastener in the hole configured to secure the base to the structure.

4. The system of claim 1 further comprising a plurality of fasteners configured to secure the plate to the base.

5. The system of claim 1, wherein the securing mechanism comprises a plurality of threaded fasteners threadably attached to the structure, the base includes a plurality of through holes configured to receive the fasteners, and the at least one slot comprises a plurality of slots aligned with the openings configured to receive the fasteners.

6. The system of claim 5, wherein the plurality of slots comprises:
a first slot having an opening along the peripheral edge of the plate; and
a second slot having an opening along another edge of the plate.

7. The system of claim 6, wherein the first slot comprises an L-shaped slot.

8. The system of claim 6, further comprising a third slot having an opening along the peripheral edge of the plate.

9. The system of claim 5, wherein the plurality of slots comprises:
a first slot including an elongated channel having an opening along the peripheral edge and a notch disposed adjacent a portion of the elongated channel; and
a second slot including an elongated channel having an opening along the peripheral edge and a notch disposed adjacent a portion of the elongated channel.

10. The system of claim 9, wherein a length of an elongated channel of the first slot is greater than a length of an elongated channel of the second slot.

11. The system of claim 1, wherein the structure comprises a fascia and the plate comprises a rigid metal.

12. A method for mounting a satellite antenna to a structure comprising:
providing a base configured for attachment to the antenna and to the structure with a portion projecting from the structure;
providing at least one securing mechanism configured to secure the base to the structure with a space therebetween in a first position and to rigidly secure the base to the structure in a second position;
with the base in the first position, sliding a plate having at least one slot along a peripheral edge thereof in the space between the base and the structure with the slot aligned with and preventing interference of the plate with the securing mechanism; and
following the sliding operation, operating the securing mechanism to secure the base to the structure in the second position with the plate supporting the portion projecting from the structure and the slot receiving the securing mechanism.

13. The method of claim 12, further comprising attaching the plate to the base.

14. The method of claim 12, wherein the base includes a through hole and the securing mechanism comprises a fastener in the hole configured to secure the base and the plate to the structure.

15. A system comprising:
a plate including a first surface configured to slide between the structure and an object mounted to the structure with at least one securing mechanism;
a first slot positioned along a first peripheral edge of the plate, the first slot configured to align with and prevent interference of the plate with the securing mechanism during the slide and to receive the securing mechanism; and
a second slot positioned along the first peripheral edge, the second slot configured to align with and prevent interference of the plate with the securing mechanism during the slide and to receive the securing mechanism.

16. The system of claim 15, wherein the first slot comprises an elongated channel having an opening on a first end along the first peripheral edge, the first slot further comprising a notch adjacent the elongated channel disposed on an opposing second end of the elongated channel.

17. The system of claim 16, wherein the securing mechanism comprises a threaded member and wherein the threaded member slides along the elongated channel into the notch.

18. The system of claim 15, wherein the second slot comprises a notch having an opening along a second peripheral edge of the plate configured to receive a second threaded member.

19. The system of claim 16, further comprising:
a third slot comprising an elongated channel having an opening on a first end along the first peripheral edge, the third slot further comprising a notch adjacent the elongated channel disposed on an opposing second end of the elongated channel, wherein a third threaded member slides along the elongated channel into the notch.

20. The system of claim 15, wherein the plate comprises a plurality of through holes positioned proximate a third edge of the plate, the through holes configured to receive fasteners, the fasteners configured to secure the plate to the base.

21. The system of claim 19, wherein the openings are positioned in correspondence with openings of a base of a satellite antenna.
